(19) United States
(12) Patent Application Publication
(10) Pub. No.: US 2016/0225784 A1
(43) Pub. Date: Aug. 4, 2016

(54) METHOD FOR MANUFACTURING SEMICONDUCTOR DEVICE

(71) Applicant: KABUSHIKI KAISHA TOSHIBA, Tokyo (JP)

(72) Inventor: Mitsuhiro OMURA, Kuwana (JP)

(21) Appl. No.: 14/740,810

(22) Filed: Jun. 16, 2015

Related U.S. Application Data
(60) Provisional application No. 62/109,276, filed on Jan. 29, 2015.

(51) Int. Cl. H01L 27/115; H01L 21/033; H01L 21/311; H01L 21/768; H01L 21/28

(52) U.S. Cl. CPC H01L 27/11582; H01L 21/76802; H01L 21/76877; H01L 21/28282; H01L 21/31116; H01L 21/0332; H01L 21/0335; H01L 21/0337; H01L 21/31144

(57) ABSTRACT

According to one embodiment, a method for manufacturing a semiconductor device includes modifying surfaces of the first mask films and surfaces of the second mask films. The method includes setting back one first mask film in the first direction until a second mask film adjacent to the one first mask film in the first direction is exposed, by etching with selectivity with respect to modified surfaces of the first and second mask films, and broadening an exposed region of the multilayer body. The method includes etching one stacked film exposed at a surface side in the exposed region of the multilayer body, in the stacking direction.

### CROSS-REFERENCE TO RELATED APPLICATION

This application is based upon and claims the benefit of priority from U.S. Provision& Patent Application 62/109,276, filed on Jan. 29, 2015; the entire contents of which are incorporated herein by reference.

### FIELD

Embodiments described herein relate generally to a method for manufacturing a semiconductor device.

### BACKGROUND

A memory device of a three-dimensional structure including a multilayer body has been proposed. A plurality of electrode layers are stacked in the multilayer body. A charge storage film and a semiconductor film are provided so as to extend in a stacking direction of the multilayer body.

Each of the plurality of electrode layers in such a three-dimensional memory device is connected to a control circuit by a contact structure. In a proposed contact structure, the plurality of electrode layers are processed into a staircase pattern.

A proposed method for processing the electrode layers into a staircase pattern is to alternately repeat slimming a resist film and etching part of the multilayer body including the electrode layers. However, with the increase of the number of electrode layers and the increase of the number of stairs in the staircase part of the electrode layers, the resist film may disappear while slimming of the resist film is repeated a plurality of times. Thickening the film thickness of the resist film is restricted by the resolution limit of lithography.

### BRIEF DESCRIPTION OF THE DRAWINGS

FIG. 1 is a schematic perspective view of a memory cell array of a semiconductor device of an embodiment;

FIG. 2 is a schematic sectional view of a memory cell of the semiconductor device of the embodiment;

FIG. 3 is a schematic sectional view of a staircase-shaped contact part of the semiconductor device of the embodiment; and

FIGS. 4A to 25 are schematic views showing a method for manufacturing the semiconductor device of the embodiment.

### DETAILED DESCRIPTION

According to one embodiment, a method for manufacturing a semiconductor device includes forming first mask films and second mask films on a multilayer body including two or more stacked films. One stacked film includes a first layer and a second layer made of a material different from a material of the first layer. The first mask films and the second mask films are arranged alternately in a first direction orthogonal to a stacking direction of the multilayer body. The second mask films are made of materials different from materials of the first mask films. The method includes modifying surfaces of the first mask films and surfaces of the second mask films. The method includes setting back one first mask film in the first direction until a second mask film adjacent to the one first mask film in the first direction is exposed, by etching with selectivity with respect to modified surfaces of the first and second mask films, and broadening an exposed region of the multilayer body. The method includes etching one stacked film exposed at a surface side in the exposed region of the multilayer body, in the stacking direction.

Embodiments will now be described with reference to the drawings. In the drawings, like elements are labeled with like reference numerals.

In the embodiments, a semiconductor memory device including a memory cell array of a three-dimensional structure is described as an example of the semiconductor device.

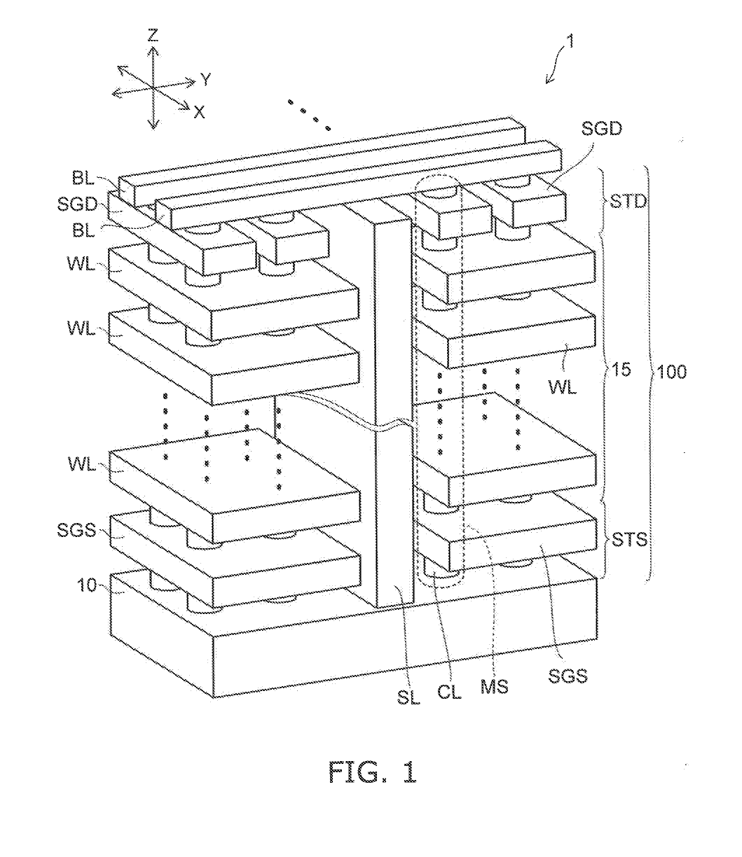

FIG. 1 is a schematic perspective view of a memory cell array 1 of an embodiment. In FIG. 1, insulating layers are not shown for clarity of illustration.

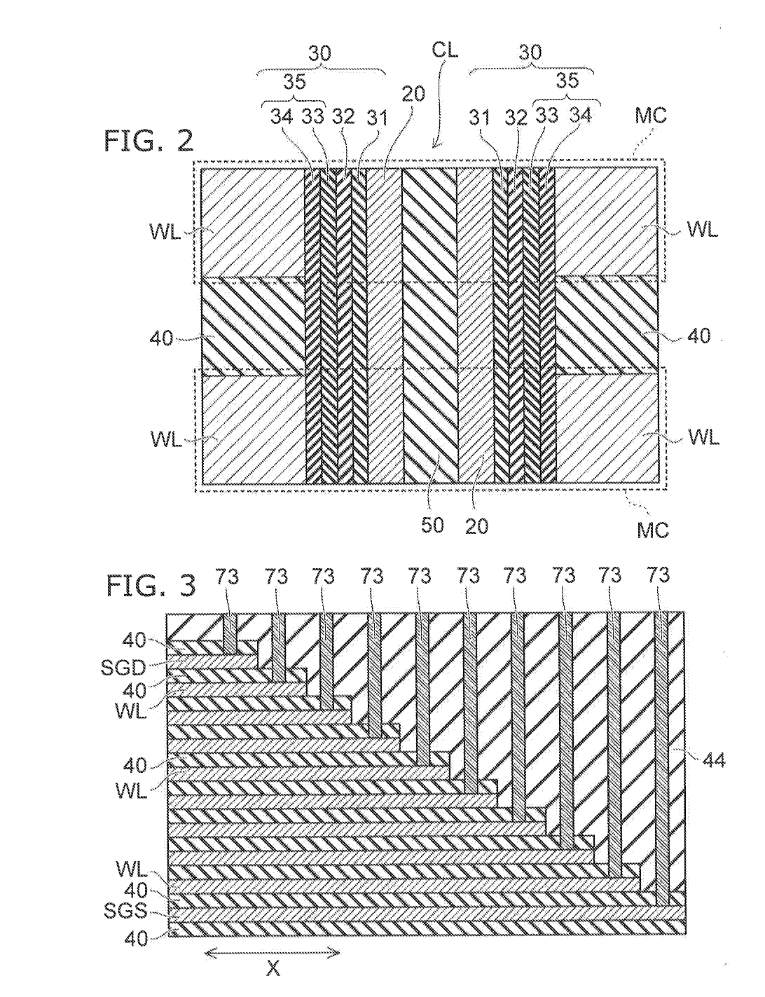

FIG. 2 is a schematic sectional view of a memory cell MC of the embodiment.

In FIG. 1, two directions parallel to the major surface of the substrate 10 and orthogonal to each other are referred to as X-direction (first direction) and Y-direction (second direction). The direction orthogonal to both the X-direction and the Y-direction is referred to as Z-direction (third direction or stacking direction).

A source side select gate (lower gate layer) SGS is provided on the substrate 10 via an insulating layer. A multilayer body 15 is provided on the source side select gate SGS. Electrode layers WL and insulating layers are alternately stacked in the multilayer body 15. The multilayer body 15 includes a plurality of electrode layers WL and a plurality of insulating layers. As shown in FIG. 2, an insulating layer 40 is provided between the electrode layers WL. A drain side select gate (upper gate layer) SGD is provided on the uppermost electrode layer WL via an insulating layer.

The source side select gate SGS, the drain side select gate SGD, and the electrode layer WL are metal layers. The source side select gate SGS, the drain side select gate SGD, and the electrode layer WL are e.g. layers primarily including tungsten. Alternatively, the source side select gate SGS, the drain side select gate SGD, and the electrode layer WL are e.g. silicon layers composed primarily of silicon. The silicon layer is doped with e.g. boron as an impurity for imparting conductivity. Alternatively, the source side select gate SGS, the drain side select gate SGD, and the electrode layer WL may include metal silicide.

A plurality of bit lines BL (e.g., metal films) are provided on the drain side select gate SGD via an insulating layer.

A plurality of drain side select gates SGD are separated in the Y-direction, each corresponding to the row of a plurality of columnar parts CL arranged in the X-direction. Each drain side select gate SGD extends in the X-direction.

The bit lines BL are separated in the X-direction, each corresponding to the row of a plurality of columnar parts CL arranged in the Y-direction. Each bit line BL extends in the Y-direction.

A plurality of columnar parts CL penetrate through the multilayer body 100 including the source side select gate SGS, the multilayer body 15 including a plurality of electrode layers WL, and the drain side select gate SGD. The columnar part CL extends in the stacking direction (Z-direction) of the multilayer body 15. The columnar part CL is formed like e.g. a circular cylinder or an elliptic cylinder.

The multilayer body 100 is separated into a plurality in the Y-direction. A source layer SL, for instance, is provided in the separating part.

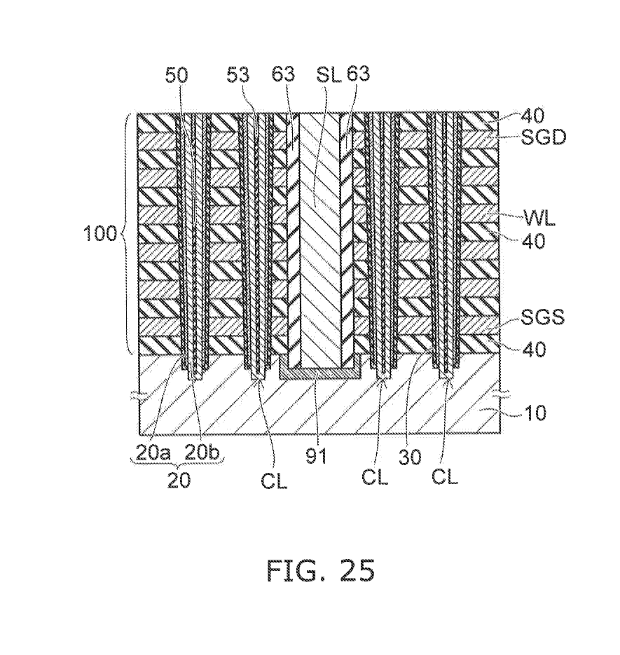

The source layer SL includes a metal (e.g., tungsten). The lower end of the source layer SL is connected to the substrate 10. The upper end of the source layer SL is connected to an upper interconnection, not shown. An insulating film 63 shown in FIG. 25 is provided between the source layer SL and the electrode layer WL, between the source layer SL and the source side select gate SGS, and between the source layer SL and the drain side select gate SGD, described later.

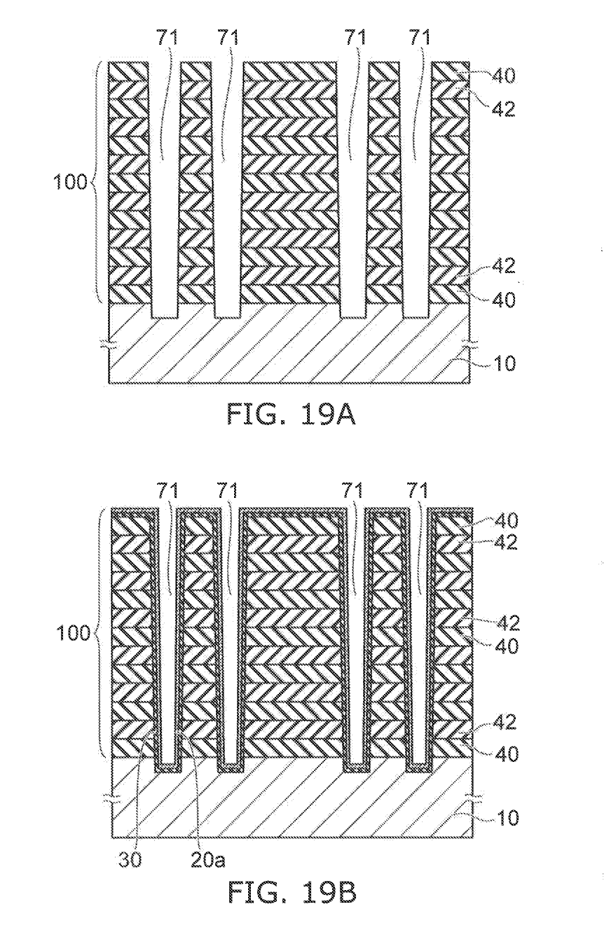

The columnar part CL is formed in a memory hole 71 (shown in FIG. 19A) formed in the multilayer body 100. A semiconductor film (semiconductor body) 20 shown in FIG. 2 is provided in the memory hole 71. The semiconductor film 20 is e.g. a silicon film composed primarily of silicon. The semiconductor film 20 includes substantially no impurity.

The semiconductor film 20 is formed like a pipe extending in the stacking direction of the multilayer body 100. The upper end part of the semiconductor film 20 penetrates through the drain side select gate SGD and is connected to the bit line BL shown in FIG. 1.

The lower end part of the semiconductor film 20 penetrates through the source side select gate SGS and is connected to the substrate 10. The lower end part of the semiconductor film 20 is electrically connected to the source layer SL through the substrate 10.

As shown in FIG. 2, a memory film 30 is provided between the sidewall of the memory hole and the semiconductor film 20. The memory film 30 includes a block insulating film 35, a charge storage film 32, and a tunnel insulating film 31. The memory film 30 is formed like a pipe extending in the stacking direction of the multilayer body 100.

The block insulating film 35, the charge storage film 32, and the tunnel insulating film 31 are provided sequentially from the electrode layer WL side between the electrode layer WL and the semiconductor film 20. The block insulating film 35 is in contact with the electrode layer WL. The tunnel insulating film 31 is in contact with the semiconductor film 20. The charge storage film 32 is provided between the block insulating film 35 and the tunnel insulating film 31.

The memory film 30 surrounds the outer periphery of the semiconductor film 20. The electrode layer WL surrounds the outer periphery of the semiconductor film 20 via the memory film 30. A core insulating film 50 is provided inside the semiconductor film 20.

The electrode layer WL functions as a control gate of the memory cell MC. The charge storage film 32 functions as a data storage layer for storing charge injected from the semiconductor film 20. A memory cell MC is formed in the crossing portion of the semiconductor film 20 and each electrode layer WL. The memory cell MC has a vertical transistor structure in which the semiconductor film 20 is surrounded with the control gate.

The semiconductor device of the embodiment is a nonvolatile semiconductor memory device capable of electrically and freely erasing/writing data and retaining its memory content even when powered off.

The memory cell MC is e.g. a charge trap type memory cell. The charge storage film 32 includes a large number of trap sites for trapping charge, and includes e.g. a silicon nitride film.

The tunnel insulating film 31 serves as a potential barrier when charge is injected from the semiconductor film 20 into the charge storage film 32, or when the charge stored in the charge storage film 32 is diffused into the semiconductor film 20. The tunnel insulating film 31 includes e.g. a silicon oxide film. The tunnel insulating film 31 may be a stacked film of a structure in which a silicon nitride film is interposed between a pair of silicon oxide films (ONO film). The tunnel insulating film 31 made of an ONO film enables erase operation at a lower electric field than a monolayer silicon oxide film.

The block insulating film 35 prevents the charge stored in the charge storage film 32 from diffusing into the electrode layer WL. The block insulating film 35 includes a cap film 34 provided in contact with the electrode layer WL, and a block film 33 provided between the cap film 34 and the charge storage film 32.

The block film 33 is e.g. a silicon oxide film. The cap film 34 is a film having higher dielectric constant than silicon oxide film. The cap film 34 is e.g. a silicon nitride film, aluminum oxide film, hafnium oxide film, or yttrium oxide film. Such a cap film 34 provided in contact with the electrode layer WL can suppress back tunneling electrons injected from the electrode layer WL at erasure time.

As shown in FIG. 1, a drain side select transistor STD is provided in the upper end part of the columnar part CL. A source side select transistor STS is provided in the lower end part of the columnar part CL.

The memory cell MC, the drain side select transistor STD, and the source side select transistor STS are vertical transistors in which the current flows in the stacking direction (Z-direction) of the multilayer body 100.

The drain side select gate SGD functions as a gate electrode (control gate) of the drain side select transistor STD. An insulating film functioning as a gate insulating film of the drain side select transistor STD is provided between the drain side select gate SGD and the semiconductor film 20.

The source side select gate SGS functions as a gate electrode (control gate) of the source side select transistor STS. An insulating film functioning as a gate insulating film of the source side select transistor STS is provided between the source side select gate SGS and the semiconductor film 20.

A plurality of memory cells MC with the respective electrode layers WL serving as control gates are provided between the drain side select transistor STD and the source side select transistor STS. The plurality of memory cells MC, the drain side select transistor STD, and the source side select transistor STS are series connected through the semiconductor film 20 to constitute one memory string MS. This memory string MS is arranged in a plurality in the X-direction and the Y-direction. Thus, a plurality of memory cells MC are provided three-dimensionally in the X-direction, the Y-direction, and the Z-direction.

FIG. 3 is a schematic sectional view of the staircase-shaped contact part of the semiconductor device of the embodiment.

Part of the multilayer body 100 including the source side select gate SGS, the drain side select gate SGD, and a plurality of electrode layers WL is processed into a staircase pattern as shown in FIG. 3. The X-direction shown in FIG. 3 corresponds to the X-direction shown in FIG. 1.

The source side select gate SGS, the drain side select gate SGD, and the electrode layers WL are processed into a staircase pattern along the X-direction. The source side select gate SGS is located in the lowermost stair of the staircase part. The drain side select gate SGD is located in the uppermost stair of the staircase part.

An insulating layer 40 is provided on each stair part of the source side select gate SGS, the drain side select gate SGD, and the electrode layer WL. The insulating layers 40 are also processed into a staircase pattern along the X-direction.

An interlayer insulating film 44 is provided on the staircase part. The interlayer insulating film 44 covers the staircase part. A plurality of vies (plugs) 73 are provided on the staircase part. The via 73 penetrates through the interlayer insulating film 44 and the insulating layer 40 of each stair. The vias 73 reach the source side select gate SGS, the drain side select gate SGD, and the electrode layers WL of the respective stairs.

The via 73 is formed from a conductive film including e.g. a metal. The vies 73 are electrically connected to the source side select gate SGS, the drain side select gate SGD, and the electrode layers WL of the respective stairs. Each via 73 is connected to an upper interconnection, not shown, provided on the multilayer body 100.

The source side select gate SGS, the drain side select gate SGD, and the electrode layer WL of the staircase-shaped contact part are integrally connected to the source side select gate SGS, the drain side select gate SGD, and the electrode layer WL of the memory cell array 1, respectively.

Thus, each of the source side select gate SGS, the drain side select gate SGD, and the electrode layer WL of the memory cell array 1 is connected to the upper interconnection through the via 73 of the staircase-shaped contact part. The upper interconnection is connected to e.g. a control circuit formed on the surface of the substrate 10. The control circuit controls the operation of the memory cell array 1.

A proposed method for processing a plurality of electrode layers WL into a staircase pattern is to repeat slimming and etching a plurality of times. The slimming step reduces the planar size of a resist film. The etching step etches one insulating layer 40 and one electrode layer WL using the resist film as a mask. The resist film is isotropically etched. The film thickness of the resist film also decreases with the reduction of the planar size.

Currently, the film thickness of the resist film is restricted to approximately several μm by the resolution limit of lithography. On the other hand, the width of the terrace portion of each stair of the staircase part (the X-direction width in FIG. 3), i.e., the setback amount (slimming amount) of the resist film per one time, is approximately several hundred nm to 1 μm. With the increase of the number of stacked electrode layers WL and the increase of the number of times of slimming the resist film, the resist film may disappear before completing staircase processing for all the electrode layers WL.

A possible method for solving this problem may be considered as follows. During the staircase processing, the thin residual resist film is once removed by asking. The staircase processing part is further subjected to chemical treatment. Then, a resist film is applied again and patterned by lithography. Furthermore, slimming the resist film and etching the stacked film are similarly repeated.

However, the number of cycles of removing the residual resist film, chemical treatment, and patterning the new resist film increases with the increase of the number of stairs of the electrode layers WL. This incurs a significant increase of the number of process steps and increase of cost.

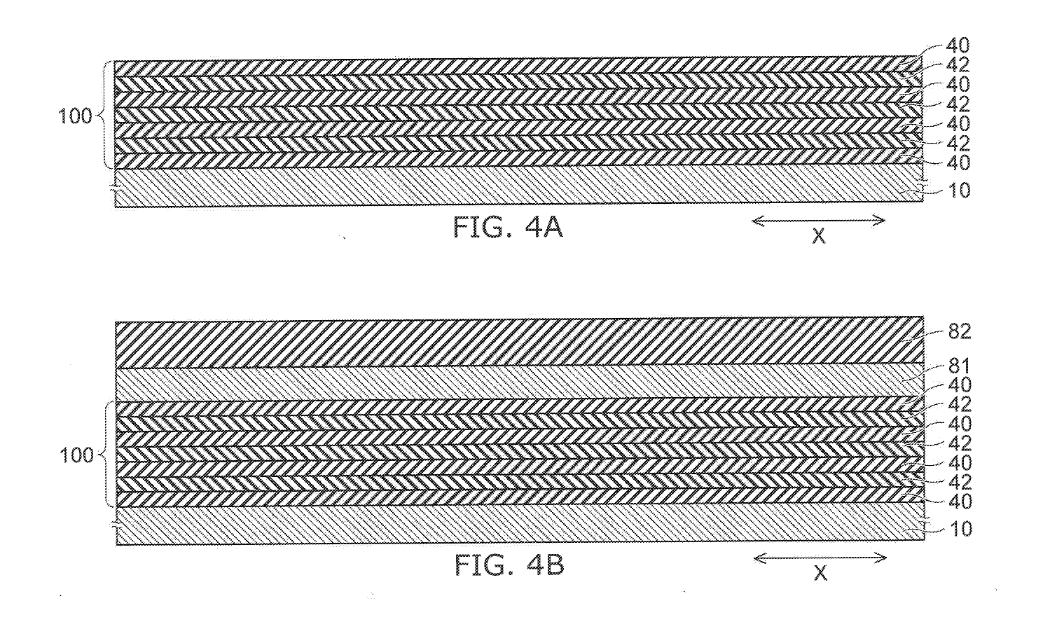

FIGS. 4A to 13 are schematic sectional views showing an example of a method for forming a staircase-shaped contact part in the semiconductor device of the embodiment.

FIGS. 4A to 13 are schematic sectional views of the region in which the staircase-shaped contact part shown in FIG. 3 is formed in the multilayer body 100. The X-direction shown in FIGS. 4A to 13 corresponds to the X-direction shown in FIG. 3.

As shown in FIG. 4A, a multilayer body 100 as a processing target layer is formed on a substrate 10. The multilayer body 100 includes a plurality of sacrificial layers (first layers) 42 and a plurality of insulating layers (second layers) 40. The substrate 10 is e.g. a semiconductor substrate such as a silicon substrate.

The insulating layers 40 and the sacrificial layers 42 are alternately formed on the substrate 10. Two or more stacked films of heterogeneous materials are formed on the substrate 10. One stacked film includes one insulating layer 40 and one sacrificial layer 42. The number of stacked layers of the sacrificial layers 42 and the insulating layers 40 is not limited to the number of layers shown in the figure.

The insulating layer 40 is e.g. a silicon oxide film. The sacrificial layer 42 is made of a material different from the insulating layer 40. The sacrificial layer 42 is e.g. a silicon nitride film. The sacrificial layers 42 will be replaced by conductive layers constituting select gates SGS, SGD and electrode layers WL in a later step.

As shown in FIG. 4B, a first mask film 81 is formed on the multilayer body 100. The first mask film 81 is e.g. a polycrystalline silicon film (first silicon film) doped with phosphorus as a first impurity.

A resist film 82 is formed on the first mask film 81. The resist film 82 is patterned by light exposure and development on the resist film 82.

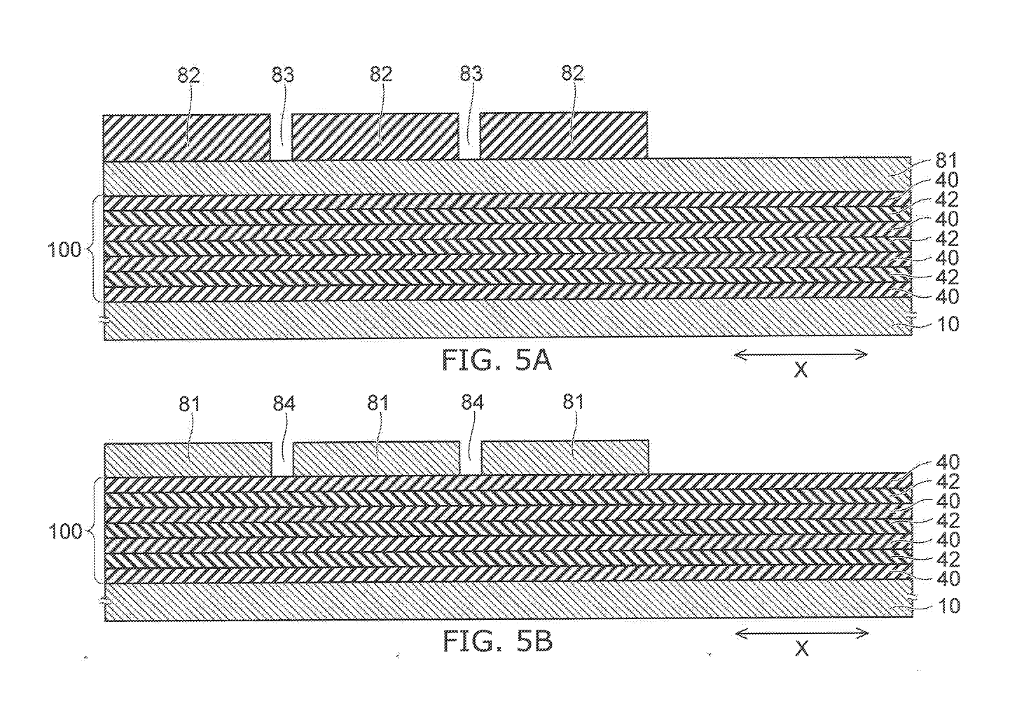

As shown in FIG. 5A, slits 83 are formed in the resist film 82. Each of the slits 83 extends in the direction traversing the page (Y-direction in FIG. 1). The resist film 82 is separated in the X-direction by the slits 83. An X-direction width of one resist film 82 separated by the slits 83 is larger than a X-direction width of one slit 83.

Next, the first mask film 81 is processed by e.g. reactive ion etching (RIE) technique using the patterned resist film 82 as a mask.

As shown in FIG. 5B, slits 84 are formed in the first mask film 81. Each of the slits 84 extends in the direction traversing the page (Y-direction in FIG. 1). The first mask film 81 is separated in the X-direction by the slits 84. An X-direction width of one first mask film 81 separated by the slits 84 is larger than the X-direction width of one slit 84. The upper surface of the multilayer body 100 (e.g., the upper surface of the insulating layer 40) is exposed at the bottoms of the slits 84.

After forming the slits 84, the remaining resist film 82 is removed by ashing and wet cleaning.

In the case where the first mask film 81 is made of a photosensitive material, the first mask film 81 can be directly patterned by light exposure and development to form slits.

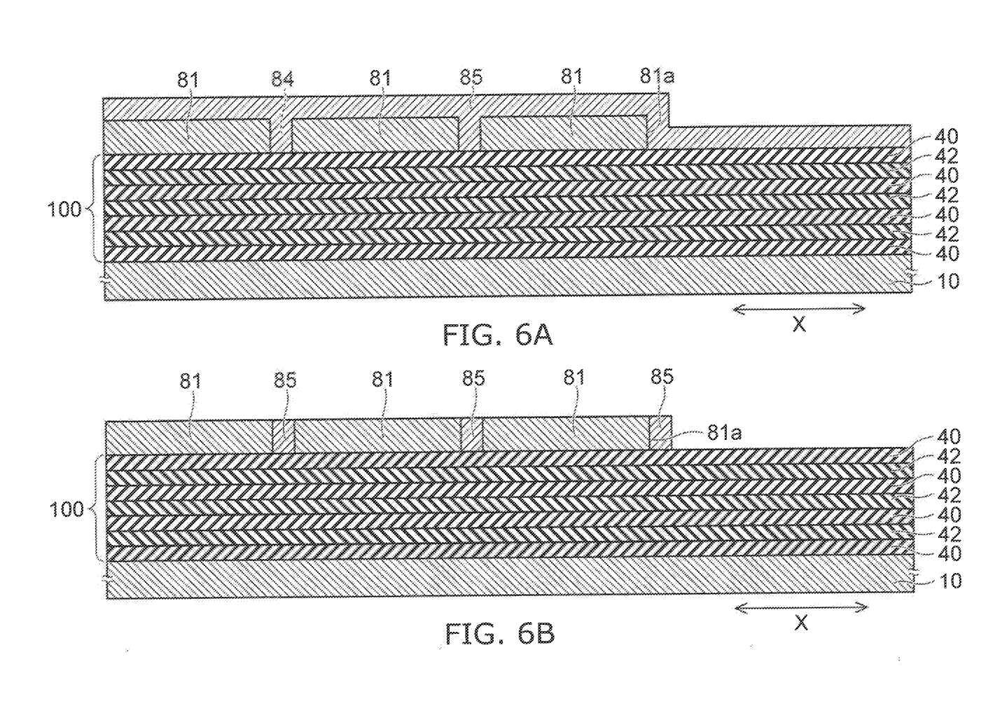

Next, as shown in FIG. 6A, a second mask film 85 is formed on the multilayer body 100 so as to cover the first mask film 81. The second mask film 85 is buried in the slits 84.

The second mask film 85 is a polycrystalline silicon film (second silicon film) doped with boron as a second impurity. The second impurity is different from the first impurity (phosphorus) used for doping the first mask film 81. That is, the second mask film 85 is a film made of a material different from that of the first mask film 81. The second mask film 85 has etching selectivity with respect to the first mask film 81.

Next, the second mask film 85 is etched back in the stacking direction of the multilayer body 100 by e.g. anisotropic dry etching such as RIE technique using a mixed gas of HBr, Cl₂, and O₂.

Thus, the second mask film 85 on the first mask film 81 and the second mask film 85 on the upper surface of the multilayer body 100 are removed. As shown in FIG. 6B, the upper surface of the first mask film 81 is exposed. Furthermore, the upper surface of the multilayer body 100 is exposed in the region in which the first mask film 81 is not formed. The second mask films 85 buried in the slits 84 are left.

The second mask film 85 is left also on the sidewall 81a of the first mask film 81 at the pattern edge (the edge on one X-direction end side).

Alternatively, the second mask film 85 on the sidewall 81a may be removed by isotropic etching. In this case, as shown in FIG. 13, the second mask film 85 is not left on the sidewall 81a of the first mask film 81 at the pattern edge.

Thus, a mask is formed on the multilayer body 100. In the mask, the first mask films 81 and the second mask films 85 made of heterogeneous materials are alternately arranged in the X-direction. The first mask films 81 and the second mask films 85 extend in the direction traversing the page (Y-direction in FIG. 1). The first mask films 81 are separated in the X-direction by the second mask films 85. An X-direction width of one first mask film 81 is larger than an X-direction width of one second mask film 85.

The first mask films 81 and the second mask films 85 are made of materials different from that of the multilayer body 100 (insulating layer 40 and sacrificial layer 42). The multilayer body 100 is etched by using the first mask films 81 and the second mask films 85 as a mask.

The exposed region of the multilayer body 100 not covered with the first mask films 81 and the second mask films 85 is etched by e.g. RIE technique using a fluorocarbon-based gas.

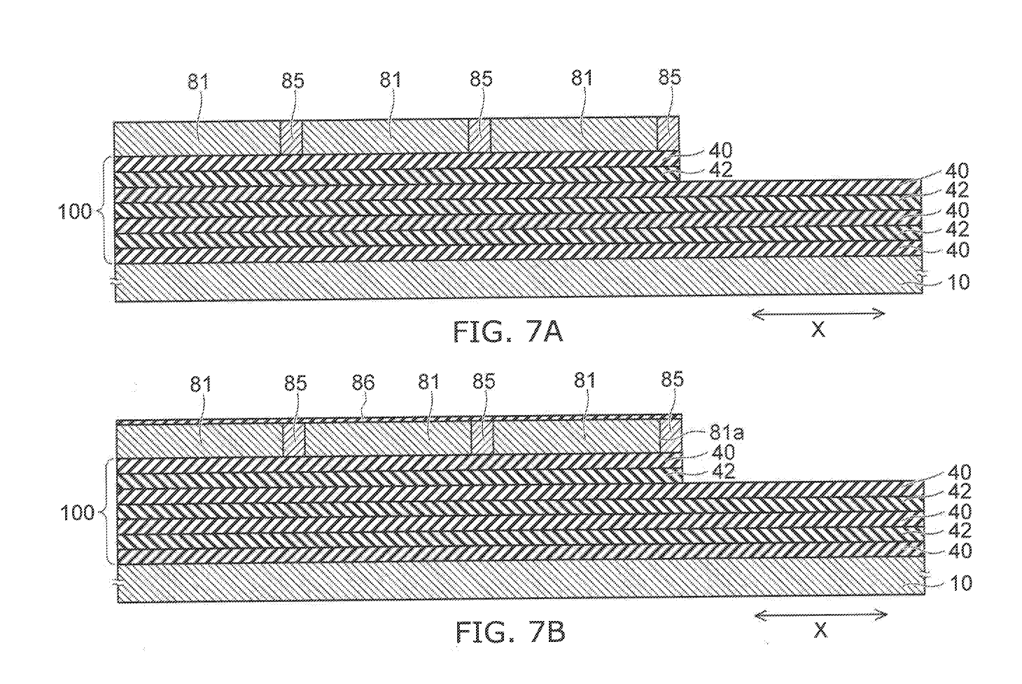

As shown in FIG. 7A, one stacked film (one insulating layer 40 and one sacrificial layer 42) at the surface side of the exposed region of the multilayer body 100 is etched and removed.

Thus, a step difference is formed in the multilayer body 100 between the surface covered with the first and second mask films 81, 85, and the exposed surface.

Next, the surfaces of the first mask films 81 and the surfaces of the second mask films 85 are modified. For instance, the surfaces of the first mask films 81 and the surfaces of the second mask films 85, both being silicon films, are oxidized by anisotropic plasma processing with oxygen gas (O₂ gas).

A processing target wafer having the multilayer structure shown in FIG. 7A is set in a chamber. Oxygen gas is introduced into the chamber to generate a plasma. A bias potential is applied to the wafer side. Thus, reaction species in the chamber are attracted to the wafer surface.

By the aforementioned surface modifying treatment, as shown in FIG. 78, a silicon oxide film 86 is formed on the surfaces of the first mask films 81 and the surfaces of the second mask films 85. The insulating layer 40 exposed in the exposed region of the multilayer body 100 is a silicon oxide film. Thus, the surface of the insulating layer 40 is not modified.

Next, the mask of a structure with the first mask films 81 and the second mask films 85 stacked alternately in the X-direction is subjected to side etching from the pattern edge (right edge in FIG. 7B). Thus, the mask is set back in the X-direction.

That is, what is called the slimming processing is performed. The planar size of the mask is reduced in the slimming processing. At this time, one second mask film 85 and one first mask film 81 are set back in the X-direction by etching having etching selectivity with respect to the oxidized surface. Thus, the silicon oxide film 86 at the surface serves as a protective film. The silicon oxide film 86 can prevent reduction of the thickness of the portion of the mask remaining on the multilayer body 100. The silicon oxide film 86 can prevent reduction of the thickness in the stacking direction of the multilayer body 100.

In the example shown in FIG. 78, the second mask film 85 is left at the pattern edge of the mask. The second mask film 85 is etched by isotropic plasma processing using e.g. a fluorine-containing gas as a first gas. For instance, NF₃ gas or SF₆ gas is introduced into the etching chamber. The pressure in the etching chamber is set to several hundred mT or more. A plasma is generated in the etching chamber.

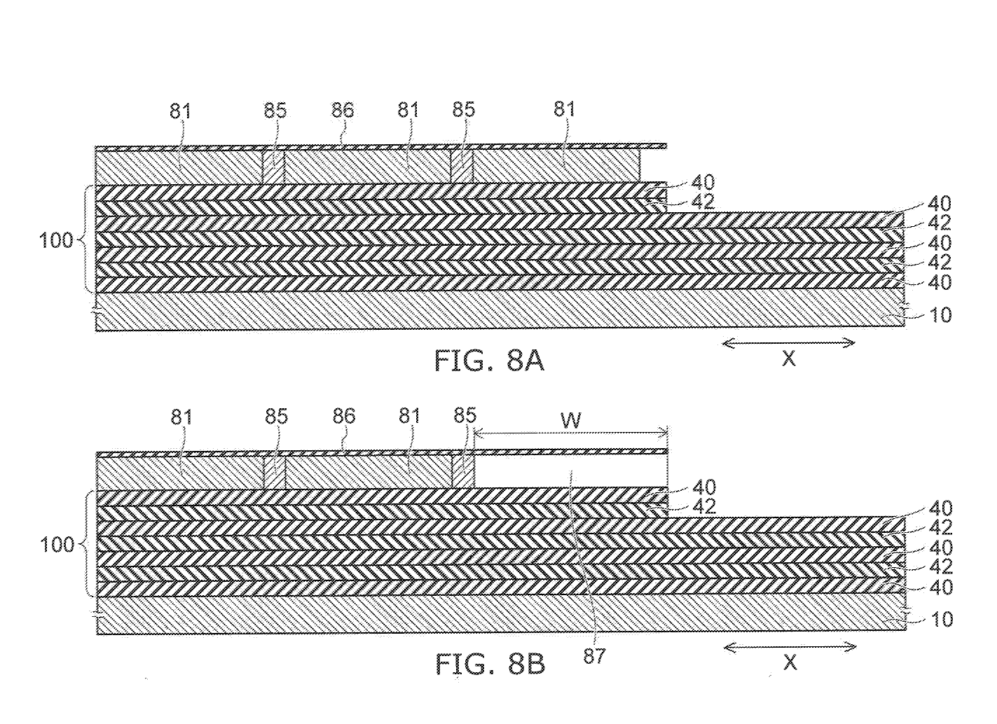

By this plasma processing, the second mask film 85 at the pattern edge is removed as shown in FIG. 8A. Ions are not accelerated with energy toward the wafer. The second mask film 85 is etched primarily by F (fluorine) radicals. The silicon oxide film 86 at the surface is scarcely etched. Thus, as shown in FIG. 8A, part of the silicon oxide film 86 is left like an overhang above the space at the pattern edge by removing the second mask film 85.

At the time of the side etching of the second mask film 85 and the first mask film 81, the insulating layer 40 made of silicon oxide film of the multilayer body 100 is not etched. The condition setting can be adjusted to suppress the etching of the sacrificial layer 42 made of silicon nitride film. Because the sacrificial layer 42 will be replaced by e.g. an electrode layer WL in a later step, the sacrificial layer 42 may be slightly etched.

By the removal of the second mask film 85 at the pattern edge, the first mask film 81 adjacent to the second mask film 85 is exposed at the pattern edge of the mask, as shown in FIG. 8A.

At the time of the aforementioned etching using a fluorine-containing gas, the etching rate of the first mask film 81 made of phosphorus-doped silicon film can be made nearly equal to that of the second mask film 85 made of boron-doped silicon film by adjusting plasma density and electron temperature.

When the second mask film 85 is etched, the first mask film 81 is not required for an etching stopper. The etching may not be immediately stopped when the second mask film 85 has disappeared. Side etching may proceed into the first mask film 81.

The second mask film 85 is removed, and the first mask film 81 adjacent thereto appears as shown in FIG. 8A. Before the first mask film 81 disappears, the gas introduced into the chamber is switched from the first gas to a second gas. Then, the etching of the first mask film 81 is continued.

The first mask film 81 is etched by isotropic plasma processing using e.g. a chlorine-containing gas as a second gas. For instance, Cl₂ gas is introduced into the etching chamber. A plasma is generated in the etching chamber.

The first mask film 81 at the pattern edge is set back in the X-direction and removed as shown in FIG. 8B. Also at this time, ions are not accelerated with energy toward the wafer. The first mask film 81 is etched primarily by Cl (chlorine) radicals. Furthermore, the silicon oxide film 86 at the surface is scarcely etched. Part of the silicon oxide film 86 is left like an overhang above a space 87 at the pattern edge, as shown in FIG. 8B. The space 87 is formed by the removal of the first mask film 81.

By the removal of the first mask film 81 at the pattern edge, the second mask film 85 adjacent to the first mask film 81 is exposed at the pattern edge of the mask. The exposed region of the multilayer body 100 is broadened by the X-direction etch back of the first mask film 81.

Cl radicals have a lower reactivity with the boron-doped silicon film than F radicals. Thus, the second mask film 85 made of boron-doped silicon film is etched less easily than the first mask film 81 made of phosphorus-doped silicon film. Accordingly, the first mask film 81 is etched at a higher rate than the second mask film 85. That is, the second mask film 85 can be used to function as a stopper for etching the first mask film 81. This facilitates control for stopping etching when the first mask film 81 has disappeared.

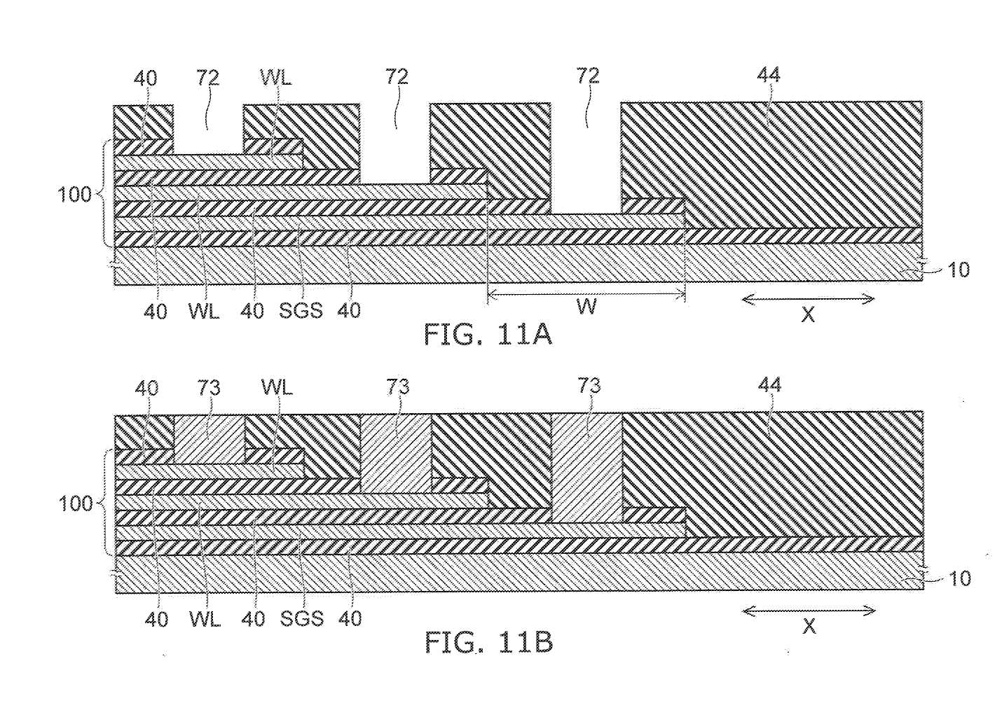

Thus, the slimming amount of the mask in the X-direction is easily controlled. This slimming amount corresponds to the X-direction width of the newly exposed region of the multilayer body 100, i.e., the terrace width W of one stair. That is, the width W of the region to which the contact hole 72 is extended in the later step shown in FIG. 11A can be controlled with high accuracy. Thus, the overall width of the staircase structure is not unnecessarily widened while ensuring a sufficient width for forming the contact hole 72.

Next, the exposed region of the multilayer body 100 is etched using the first mask films 81 and the second mask films 85 remaining on the multilayer body 100 as a mask.

The exposed region of the multilayer body 100 not covered with the first mask film 81 and the second mask film 85 is etched by e.g. RIE technique using a fluorocarbon-based gas.

One stacked film (one insulating layer 40 and one sacrificial layer 42) at the surface side of the exposed region of the multilayer body 100 is etched and removed. At this time, the silicon oxide film 86 is also etched and removed.

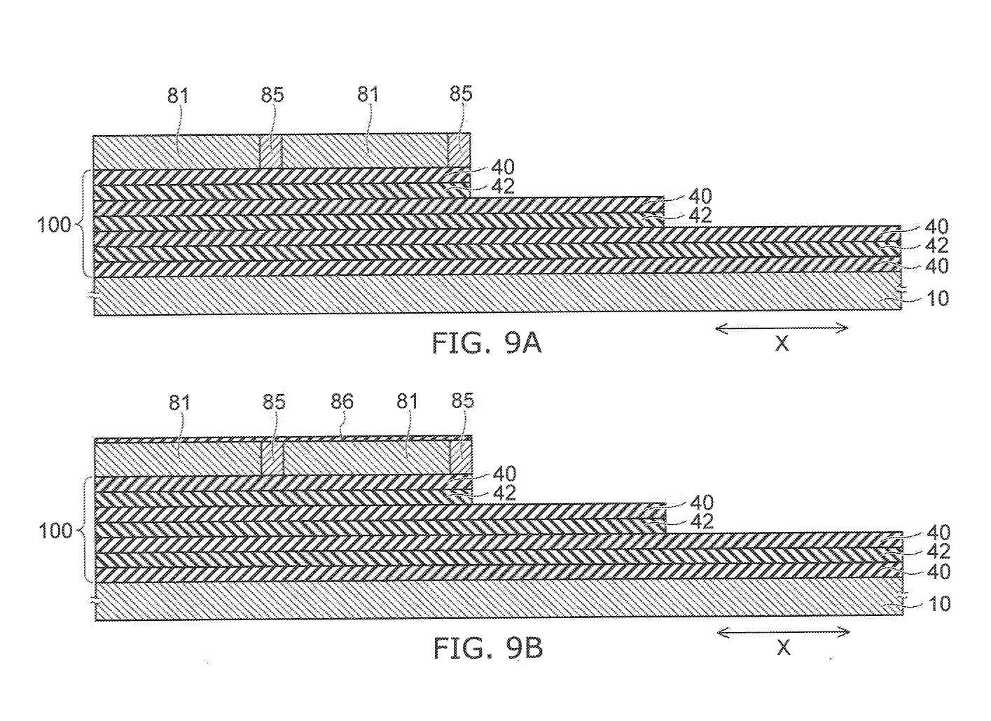

One stacked film (one insulating layer 40 and one sacrificial layer 42) exposed at the surface side in FIG. 8B is removed as shown in FIG. 9A. Removed is the exposed one stacked film in the region in which one stacked film was already removed in the previous step, and in the region newly exposed by slimming of the first mask film 81. Thus, the number of stairs is increased.

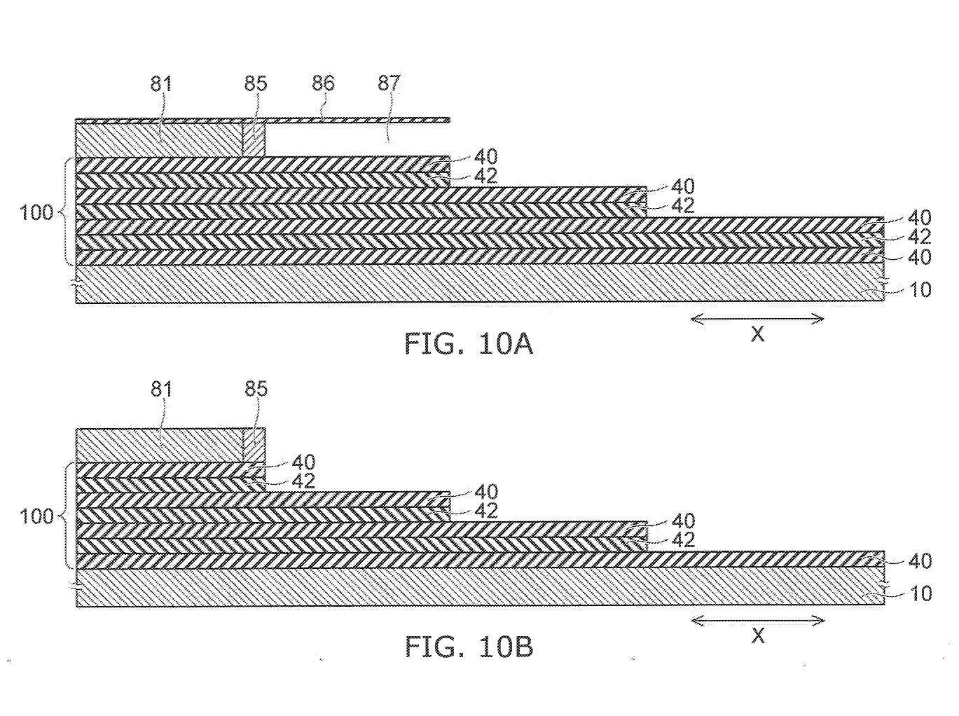

Subsequently, the steps similar to the aforementioned steps are repeated. That is, the step of modifying the surfaces of the films 85, 81 (FIG. 9B), the step of broadening the exposed region of the multilayer body 100 (FIG. 10A), and the step of increasing the number of stairs (FIG. 10B) are repeated a plurality of cycles. In the step of modifying the surfaces, the surfaces of the first and second mask films 81, 85 left on the multilayer body 100 are modified. In the step of broadening the exposed region of the multilayer body 100, the second mask film 85 at the pattern edge is removed by etching using the first gas, and the first mask film 81 is side-etched in the X-direction by etching using the second gas. In the step of increasing the number of stairs, one stacked film (one insulating layer 40 and one sacrificial layer 42) exposed at the surface side is etched. Thus, a plurality of sacrificial layers 42 are processed into a staircase pattern in the X-direction.

According to the embodiment, in forming the staircase part, the film thickness of the mask (first mask film 81 and second mask film 85) is scarcely decreased at the time of slimming. This makes it possible to form a multistage staircase by only one time of lithography for forming slit pattern in the resist film 82 in FIG. 5A. Thus, the lithography cost can be significantly reduced. There is no step of removing the mask film thinned by a plurality of times of slimming, and forming a new mask film. Thus, the cost can be reduced without incurring a significant increase of the number of steps.

Furthermore, the mask slimming amount determining the terrace width (X-direction width) W of the staircase depends on the patterning of the first mask film 81, i.e., the patterning of the resist film 82 by lithography. Thus, the staircase terrace width W can be controlled with very high accuracy. As a result, the staircase terrace width W can be easily narrowed. This can achieve miniaturization of the device.

The step of modifying the surfaces of the first and second mask films 81, 85, the step of removing the mask films 81, 85 at the pattern edge by side-etching in the X-direction, and the step of etching one stacked film (one insulating layer 40 and one sacrificial layer 42) exposed at the surface side constitute one cycle. This cycle can be continuously performed in the same etching chamber without exposure to the atmosphere.

After forming the staircase part in the multilayer body 100, an interlayer insulating film 44 is formed on the staircase part as shown in FIG. 11A. The interlayer insulating film 44 covers the staircase part.

As described later, the sacrificial layers 42 are replaced by conductive layers constituting an electrode layer WL, a drain side select gate SGD, and a source side select gate SGS. FIGS. 11A and 11B show a staircase structure of the source side select gate SGS and two electrode layers WL on a bottom side.

Then, a contact hole 72 is formed. The contact hole 72 penetrates through the interlayer insulating film 44 and the insulating layer 40 of each stair part. The contact holes 72 reach the electrode layer WL, the drain side select gate SGD, and the source side select gate SGS of the respective stair parts.

A conductive film is formed in the contact hole 72. Thus, a contact via (contact plug) 73 is formed as shown in FIGS. 11B and 3.

When the surfaces of the first mask films 81 and the surfaces of the second mask films 85 are oxidized by anisotropic plasma processing using oxygen gas, the sidewall of the second mask film 85 exposed at the pattern edge may also be oxidized. This may hamper the side etching of the second mask film 85.

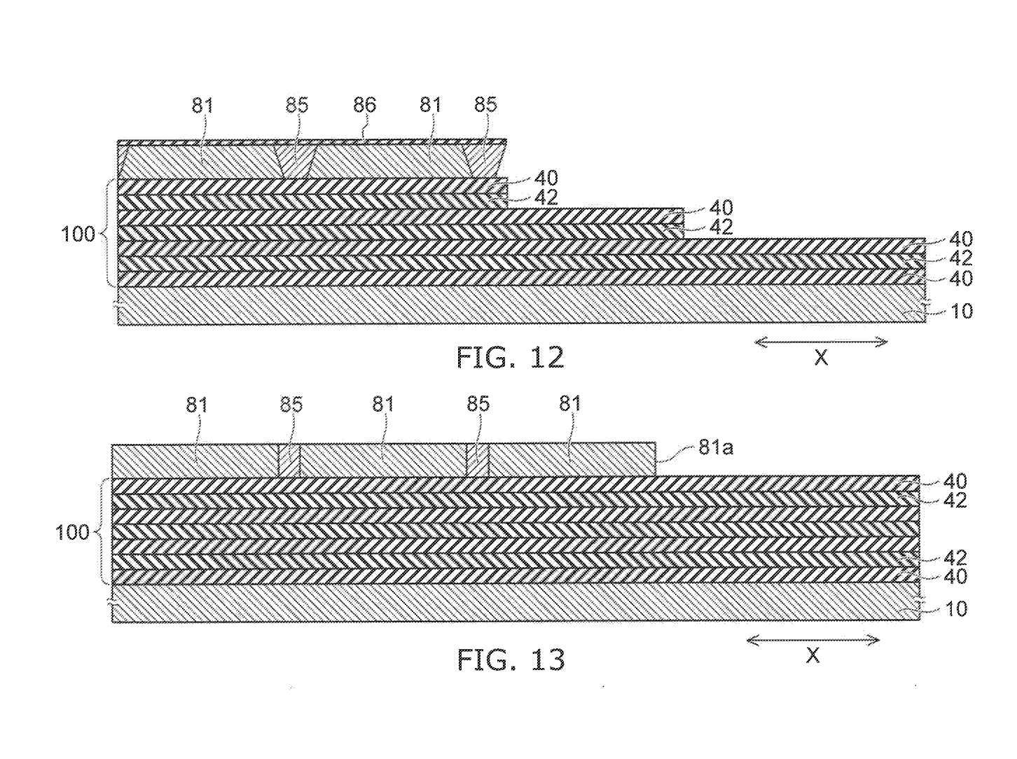

Thus, as shown in FIG. 12, the sidewall of the second mask film 85 may be inclined in what is called an inverted taper shape. Then, the sidewall of the second mask film 85 is hidden from oxygen introduced from above. Thus, the sidewall is made less prone to oxidation. This facilitates the side etching of the second mask film 85.

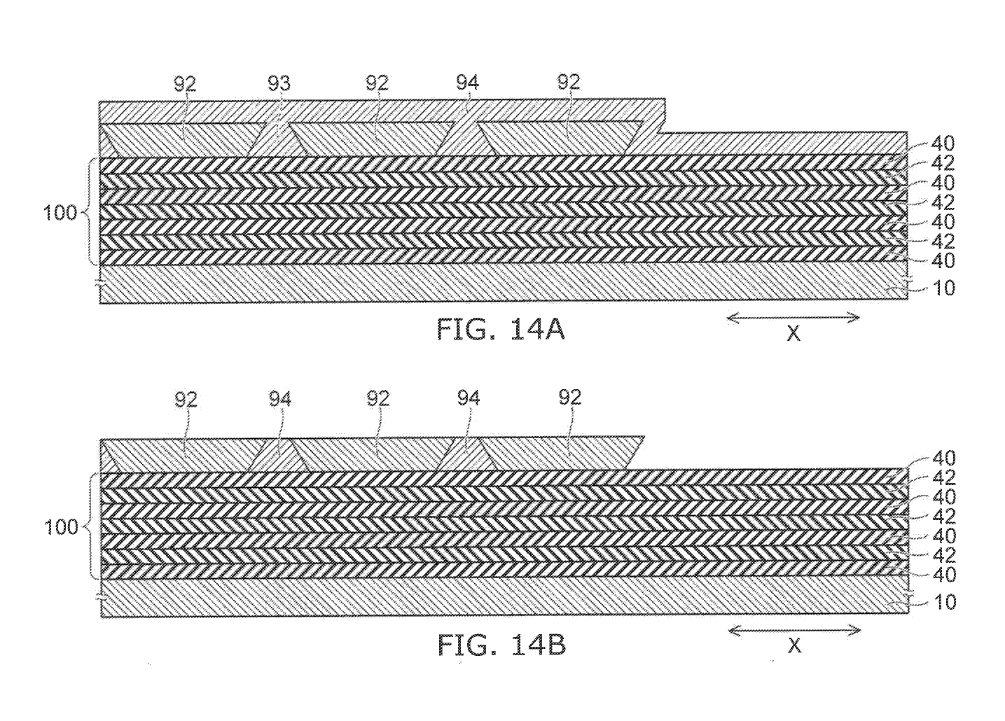

Next, FIGS. 14A to 18 are schematic sectional views showing another example of the method for forming a staircase-shaped contact part of the embodiment.

FIGS. 14A to 18 are also schematic sectional views of the region of the multilayer body 100 in which the staircase-shaped contact part shown in FIG. 3 is formed. The X-direction shown in FIGS. 14A to 18 corresponds to the X-direction shown in FIG. 3.

As shown in FIG. 14A, first mask films 92 are formed on the multilayer body 100. Furthermore, a second mask film 94 is formed so as to cover the first mask films 92.

The first mask films 92 are e.g. polycrystalline silicon films. As in the above embodiment, a film of material of the first mask films 92 is patterned using a resist film. Thus, slits 93 are formed in the film. The slits 93 extend in the direction traversing the page (Y-direction in FIG. 1). The film of material of the first mask films 92 is separated in the X-direction by the slits 93.

The cross-sectional shape of one first mask film 92 is formed in an inverted taper shape. That is, the first mask film 92 is shaped like a trapezoid in cross section. The upper surface and the sidewall of the first mask film 92 make an angle smaller than 90°. Thus, the corner of the upper surface and the sidewalk of the first mask film 92 forms an acute angle.

The second mask film 94 is a film made of a material different from that of the first mask film 92. The second mask film 94 has etching selectivity with respect to the first mask film 92. For instance, the second mask film 94 is a metal film. More specifically, the second mask film 94 is a tungsten film.

The second mask film 94 on the first mask films 92 is removed by e.g. isotropic dry etching using a mixed gas of NF₃ and O₂. And the second mask film 94 directly deposited on the upper surface of the multilayer body 100 in a region outside of the slits 93, are also removed.

Thus, the upper surfaces of the first mask films 92 are exposed as shown in FIG. 14B. Furthermore, the upper surface of the multilayer body 100 is exposed in the region in which the first mask films 92 are not formed. Furthermore, the sidewall of the first mask film 92 at the pattern edge is exposed. The second mask films 94 buried in the slits 93 are left.

Thus, a mask is formed on the multilayer body 100. In the mask, the first mask films 92 and the second mask films 94 made of heterogeneous materials are alternately arranged in the X-direction. The first mask films 92 and the second mask films 94 extend in the direction traversing the page (Y-direction in FIG. 1). The first mask films 92 are separated in the X-direction by the second mask films 94.

The cross-sectional shape of one first mask film 92 is a trapezoid having an inverted taper-shaped sidewall. The cross-sectional shape of one second mask film 94 is a trapezoid having a forward taper-shaped sidewall. The X-direction maximum width of the one first mask film 92 is larger than the X-direction minimum width of the one second mask film 94.

The first mask films 92 and the second mask films 94 are made of materials different from that of the multilayer body 100 (insulating layer 40 and sacrificial layer 42). The multilayer body 100 is etched by using the first mask films 92 and the second mask films 94 as a mask.

The exposed region of the multilayer body 100 not covered with the first and second mask films 92, 94 is etched by e.g. RIE technique using a fluorocarbon-based gas.

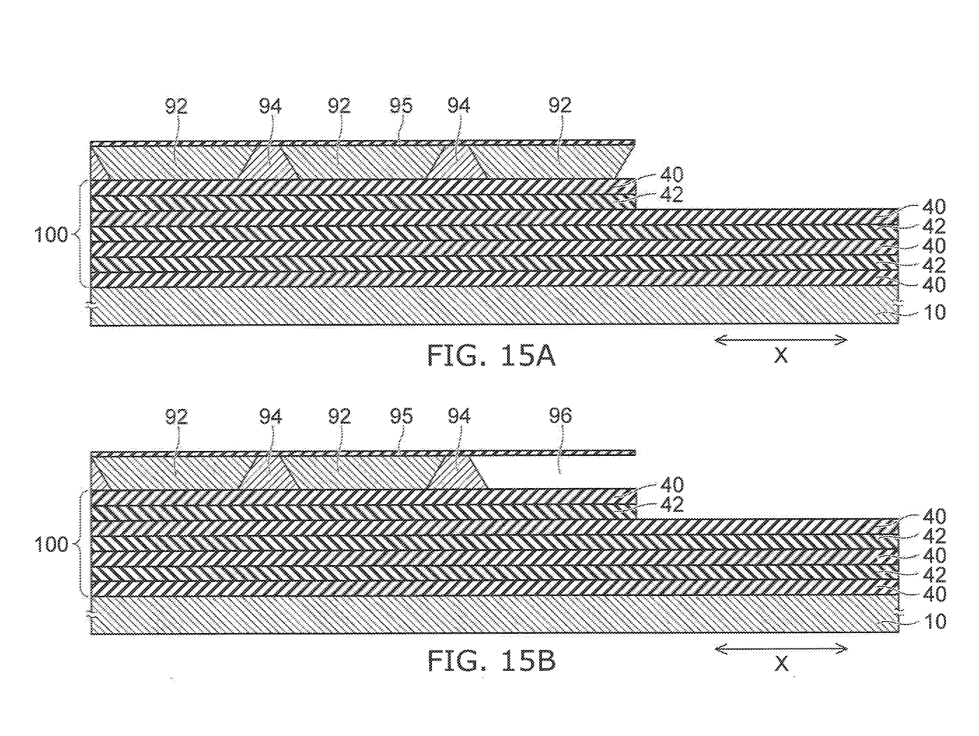

As shown in FIG. 15A, one stacked film (one insulating layer 40 and one sacrificial layer 42) at the surface side of the exposed region of the multilayer body 100 is etched and removed.

Thus, a step difference is formed in the multilayer body 100 between the surface covered with the first and second mask films 92, 94, and the exposed surface.

Next, the surfaces of the first and second mask films 92, 94 are modified. For instance, the surfaces of the first and second mask films 92, 94 are oxidized by anisotropic plasma processing with oxygen gas (O₂ gas).

A processing target wafer is set in a chamber. Oxygen gas is introduced into the chamber to generate a plasma. A bias potential is applied to the wafer side. Thus, reaction species in the chamber are attracted to the wafer surface.

By the aforementioned surface modification treatment, a silicon oxide film is formed on the upper surfaces of the first mask films 92, and a tungsten oxide film is formed on the upper surfaces of the second mask films 94. In FIG. 15A, the silicon oxide film and the tungsten oxide film are collectively shown as an oxide film (or protective film) 95.

The sidewall of the first mask film 92 at the pattern edge is inclined in what is called an inverted taper shape. Thus, the sidewall of the first mask film 92 is hidden from oxygen introduced from above. Thus, the sidewall is made less prone to oxidation. This facilitates the side etching of the first mask film 92 later.

Next, the mask of a structure with the first mask films 92 and the second mask films 94 stacked alternately in the X-direction is subjected to side etching from the pattern edge (right edge in FIG. 15A). Thus, the mask is set back in the X-direction.

That is, what is called the slimming processing is performed. The planar size of the mask is reduced in the slimming processing. At this time, one first mask film 92 and one second mask film 94 are set back in the X-direction by etching having etching selectivity with respect to the oxidized surface. Thus, the oxide film 95 at the surface serves as a protective film. The oxide film 95 can prevent reduction of the thickness of the portion of the mask remaining on the multilayer body 100. The oxide film 95 can prevent reduction of the thickness in the stacking direction of the multilayer body 100.

At the time of the side etching of the first mask film 92 and the second mask film 94, the insulating layer 40 made of silicon oxide film of the multilayer body 100 is not etched. The condition setting can be adjusted to suppress the etching of the sacrificial layer 42 made of silicon nitride film. Because the sacrificial layer 42 will be replaced by e.g. an electrode layer WL in a later step, the sacrificial layer 42 may be slightly etched.

The first mask film 92 made of silicon film is etched by isotropic plasma processing using e.g. a chlorine-containing gas (Cl₂) as a second gas. The first mask film 92 is etched with selectivity with respect to the second mask film 94 made of tungsten film. Thus, the first mask film 92 in FIG. 15A at the pattern edge, is removed as shown in FIG. 15B.

Ions are not accelerated with energy toward the wafer. The first mask film 92 is etched primarily by Cl radicals. The oxide film 95 at the surface is scarcely etched. Part of the oxide film 95 is left like an overhang above the space 96 at the pattern edge as shown in FIG. 15B. The space 96 is formed by the removal of the first mask film 92.

By the removal of the first mask film 92 at the pattern edge, the second mask film 94 adjacent to the first mask film 92 is exposed at the pattern edge of the mask.

Next, the gas introduced into the chamber is switched from the second gas to a first gas. Then, the etching of the second mask film 94 is continued.

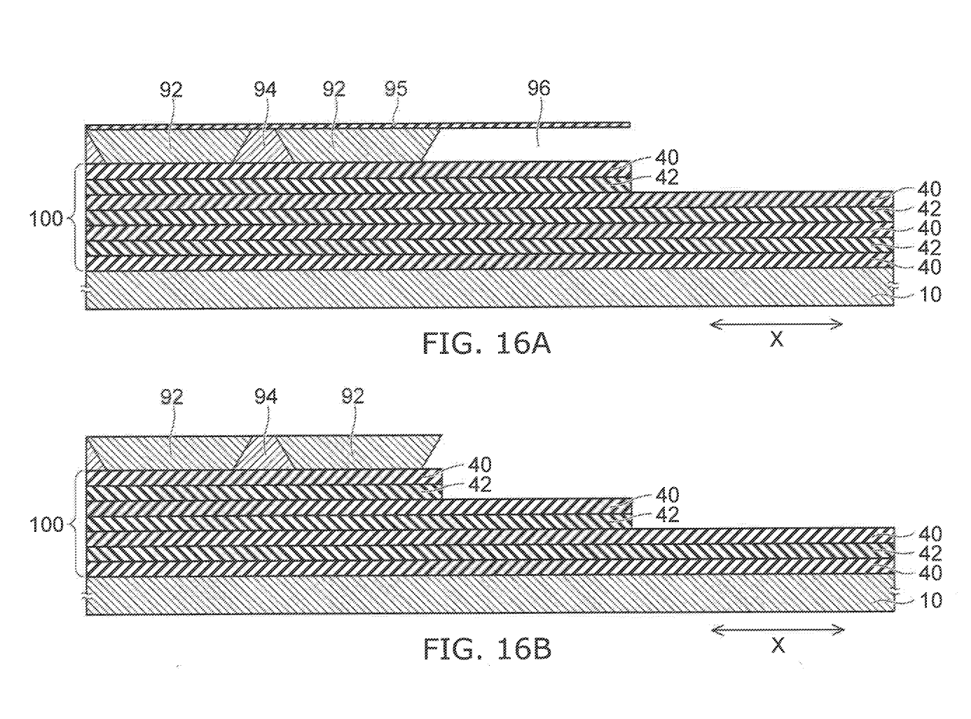

The second mask film 94 is etched by isotropic plasma processing using e.g. a gas containing fluorine and oxygen (a mixed gas of NF₃ and O₂) as a first gas. The second mask film 94 is etched with selectivity with respect to the first mask film 92. Thus, the second mask film 94 in FIG. 15B at the pattern edge, is removed as shown in FIG. 16A.

Also at this time, ions are not accelerated with energy toward the wafer. The second mask film 94 is etched primarily by F radicals. The oxide film 95 at the surface is scarcely etched.

By the removal of the second mask film 94 at the pattern edge, the inverted taper-shaped sidewall of the first mask film 92 adjacent to the second mask film 94 is newly exposed at the pattern edge of the mask.

When the second mask film 94 is removed, a silicon oxide film (SiO₂ film) is easily formed on the sidewall of the first mask film 92 by oxygen radicals contained in the etching gas. This silicon oxide film serves as a protective film. Thus, etching proceeds less easily at the sidewall of the first mask film 92 when the second mask film 94 is etched.

The sidewall of the second mask film 94 made of tungsten film is oxidized less easily than the first mask film 92 made of silicon film. The second mask film 94 is etched by fluorine radicals with selectivity with respect to the first mask film 92.

The oxide film formed by oxygen radicals at the time of isotropic etching using a mixed gas of NF₃ and O₂ is extremely thinner than the oxide film 95 on the upper surface formed by anisotropic oxygen plasma processing (oxygen ion irradiation). Thus, the oxide film on the sidewall of the first mask film 92 at the pattern edge does not significantly hamper the side etching of the first mask film 92.

The exposed region of the multilayer body 100 is broadened by the X-direction side etching of the first mask film 92 and the second mask film 94 at the pattern edge.

The first mask film 92 can be used to function as a stopper when the second mask film 94 is etched. This facilitates controlling the side etching amount (slimming amount) of the first mask film 92 and the second mask film 94.

This slimming amount corresponds to the X-direction width of the newly exposed region of the multilayer body 100, i.e., the terrace width W of one stair. Accordingly, the width of the region to which the contact hole is extended can be controlled with high accuracy. Thus, the overall width of the staircase structure is not unnecessarily widened while ensuring a sufficient width for forming the contact hole.

After the step of FIG. 16A, the exposed region of the multilayer body 100 is etched using the first mask films 92 and the second mask films 94 remaining on the multilayer body 100 as a mask.

The exposed region of the multilayer body 100 not covered with the first mask films 92 and the second mask films 94 is etched by e.g. RIE technique using a fluorocarbon-based gas.

One stacked film (one insulating layer 40 and one sacrificial layer 42) at the surface side of the exposed region of the multilayer body 100 is etched and removed. At this time, the oxide film 95 is also etched and removed.

One stacked film (one insulating layer 40 and one sacrificial layer 42) exposed at the surface side in FIG. 16A is removed. The exposed one stacked film in the region in which one stacked film was already removed in the previous step, and in the region newly exposed by slimming of the mask films 92, 94 is removed. Thus, the number of stairs is increased.

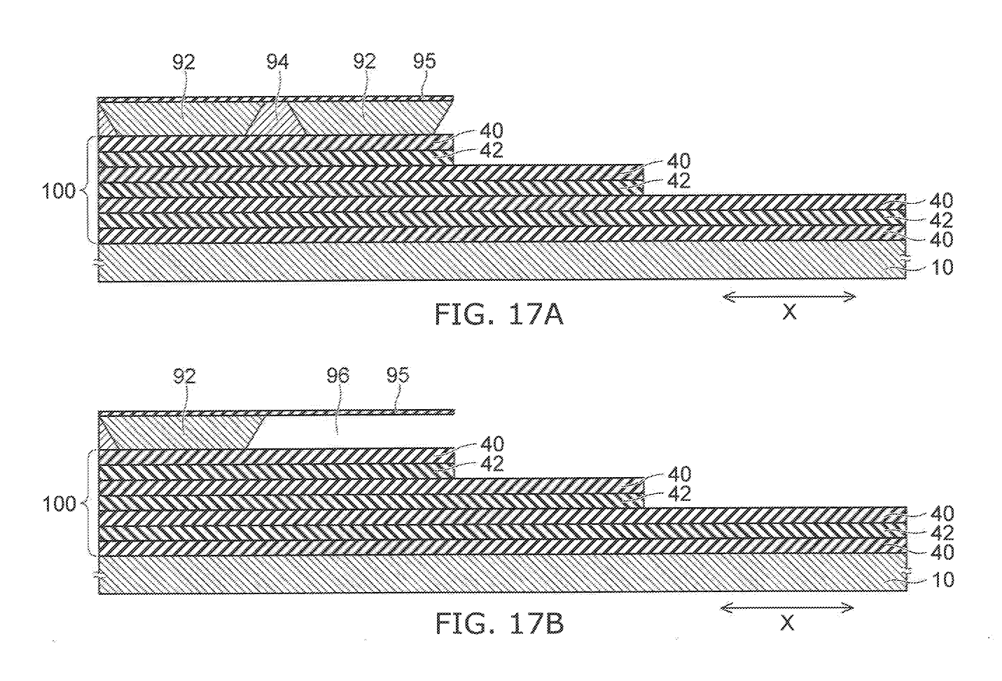

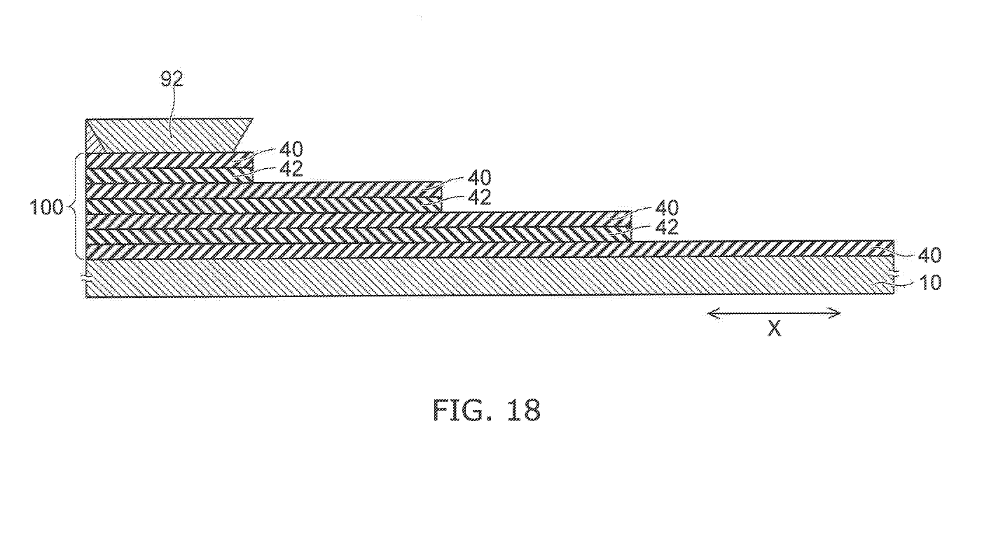

Subsequently, the steps similar to the aforementioned steps are repeated. That is, the step of modifying the surface (FIG. 17A), the step of broadening the exposed region of the multilayer body 100 (FIG. 17B), and the step of increasing the number of stairs (FIG. 18) are repeated a plurality of cycles. In the step of modifying the surface, the surfaces of the first and second mask films 92, 94 left on the multilayer body 100 are modified. In the step of broadening the exposed region of the multilayer body 100, the first mask film 92 at the pattern edge is removed, and then the second mask film 94 is removed. In the step of increasing the number of stairs, one stacked film (one insulating layer 40 and one sacrificial layer 42) exposed at the surface side is etched. Thus, a plurality of sacrificial layers 42 are processed into a staircase pattern in the X-direction.

Also in this embodiment, in forming the staircase part, the film thickness of the mask (first mask films 92 and second mask films 94) is scarcely decreased at the time of slimming. This makes it possible to form a multistage staircase by only one time of lithography for forming slit pattern in the resist film. Thus, the lithography cost can be significantly reduced. There is no step of removing the mask film thinned by a plurality of times of slimming, and forming a new mask film. Thus, the cost can be reduced without incurring a significant increase of the number of steps.

Furthermore, the mask slimming amount determining the terrace width (X-direction width) W of the staircase depends on the patterning of the first mask film 92, i.e., the patterning of the resist film by lithography. Thus, the staircase terrace width W can be controlled with very high accuracy. As a result, the staircase terrace width W can be easily narrowed. This can achieve miniaturization of the device.

The step of modifying the surfaces of the first and second mask films 92, 94, the step of removing the first and second mask films 92,94 at the pattern edge by side etching in the X-direction, and the step of etching one stacked film (one insulating layer 40 and one sacrificial layer 42) exposed at the surface side constitute one cycle. This cycle can be continuously performed in the same etching chamber without exposure to the atmosphere.

After forming the staircase part in the multilayer body 100, the interlayer insulating film 44 shown in FIG. 3 is formed on the staircase part as in the above embodiment. As described later, the sacrificial layers 42 are replaced by conductive layers constituting the electrode layer WL, the drain side select gate SGD, and the source side select gate SGS.

Then, the contact hole is formed. The contact hole penetrates through the interlayer insulating film 44 and the insulating layer 40 of each stair part. The contact holes reach the electrode layer WL, the drain side select gate SGD, and the source side select gate SGS of the respective stair parts. The conductive film is formed in the contact hole. Thus, the contact via (contact plug) 73 is formed.

Next, a method for forming the memory cell array 1 is described with reference to FIGS. 19A to 25.

The aforementioned staircase part is formed in the multilayer body 100. Furthermore, the interlayer insulating film 44 is formed on the staircase part. Then, as shown in FIG. 19A, a plurality of memory holes 71 are formed in the region of multilayer body 100 in which the memory cell array 1 is to be formed. The memory holes 71 are formed by RIE technique using a mask, not shown. The memory holes 71 penetrate through the multilayer body 100 to the substrate 10.

As shown in FIG. 19B, memory films 30 are formed on the inner walls (sidewalls and bottom parts) of the memory holes 71. Cover films 20a are formed inside the memory films 30.

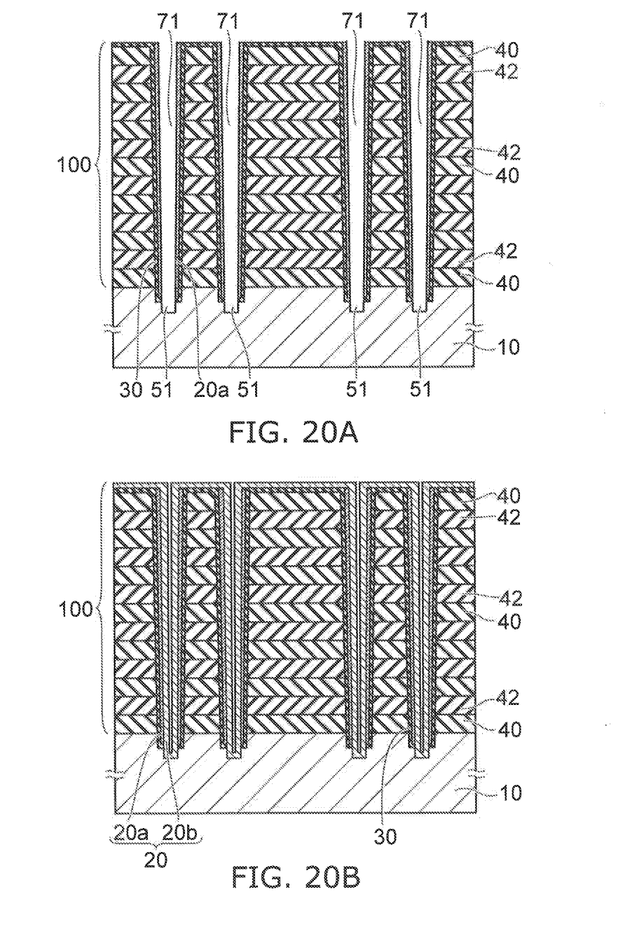

The cover films 20a and the memory films 30 formed on the bottom parts of the memory holes 71 are removed by RIE technique. Thus, as shown in FIG. 20A, holes 51 are formed in the bottom parts of the memory holes 71. The substrate 10 forms the side surfaces and the bottom surfaces of the holes 51.

At the time of this RIE, the memory films 30 formed on the sidewalls of the memory holes 71 are covered and protected with the cover films 20a. Thus, the memory films 30 formed on the sidewalls of the memory holes 71 are not damaged by RIE.

Next, as shown in FIG. 20B, semiconductor films 20b are formed in the holes 51 and inside the cover films 20a. The cover films 20a and the semiconductor films 20b are formed as amorphous silicon films, and then turned to polycrystalline silicon films by annealing treatment. The cover films 20a in conjunction with the semiconductor films 20b constitute the aforementioned semiconductor films 20.

The semiconductor films 20 are electrically connected to the substrate 10 through the semiconductor films 20b formed in the holes 51.

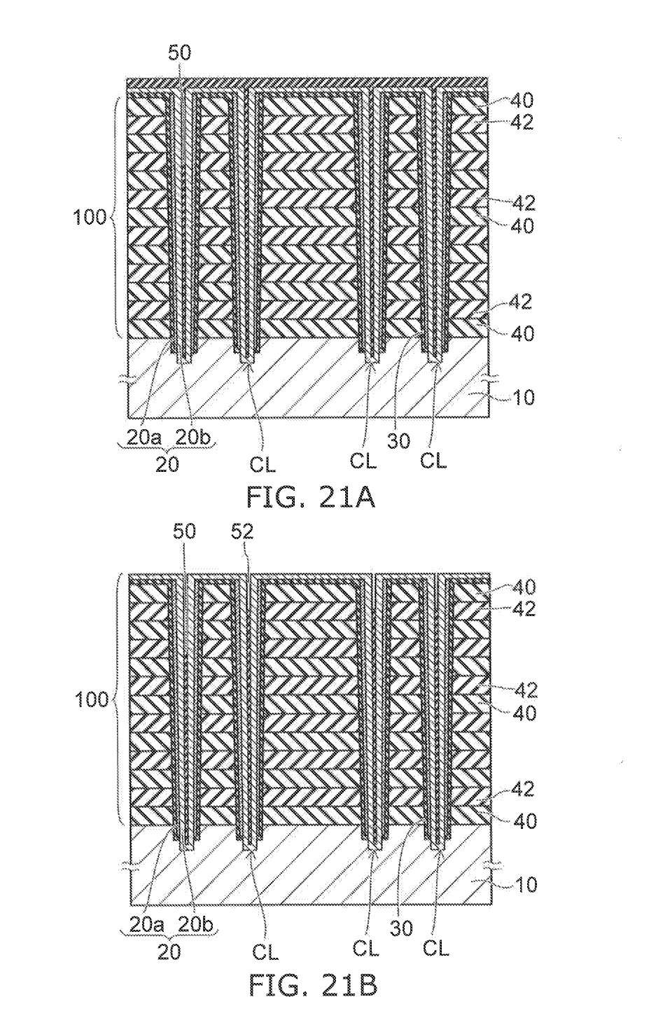

As shown in FIG. 21A, core insulating films 50 are formed inside the semiconductor films 20b. Thus, columnar parts CL are formed. The upper parts of the core insulating films 50 are etched back. Thus, as shown in FIG. 21B, voids 52 are formed in the upper parts of the columnar parts CL.

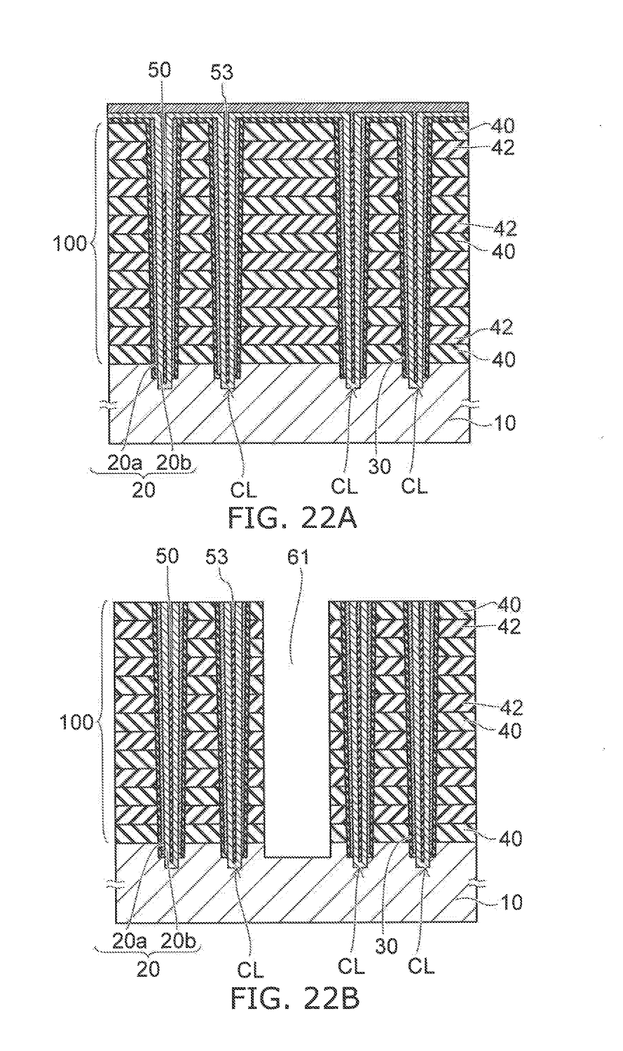

As shown in FIG. 22A, semiconductor films 53 are buried in the voids 52. The semiconductor films 53 are doped silicon films. The semiconductor films 53 have higher impurity concentration than the semiconductor films 20 made of non-doped silicon films.

In a typical memory of the charge injection type, electrons written in the charge storage layer such as a floating gate are extracted by boosting the substrate potential to erase data. An alternative erasure method is to boost the channel potential of the memory cell by utilizing a gate induced drain leakage (GIDL) current produced in the channel at the upper end of the drain side select gate.

In this embodiment, a high electric field is applied to the semiconductor film 53 of high impurity concentration formed near the upper end part of the drain side select gate SGD.

Thus, holes are generated in the semiconductor film 53. The holes are supplied to the semiconductor film 20 to boost the channel potential. The potential of the electrode layer WL is set to e.g. ground potential (0 V). Thus, the electrons in the charge storage film 32 are extracted, or the holes are injected into the charge storage film 32, by the potential difference between the semiconductor film 20 and the electrode layer WL. Accordingly, the operation of erasing data is performed.

The memory film 30, the semiconductor film 20, and the semiconductor film 53 deposited on the upper surface of the multilayer body 100 are removed after the semiconductor films 53 are buried in the voids 52.

Next, as shown in FIG. 22B, a slit 61 is formed in the multilayer body 100 by RIE technique using a mask, not shown. The slit 61 penetrates through the multilayer body 100 to the substrate 10.

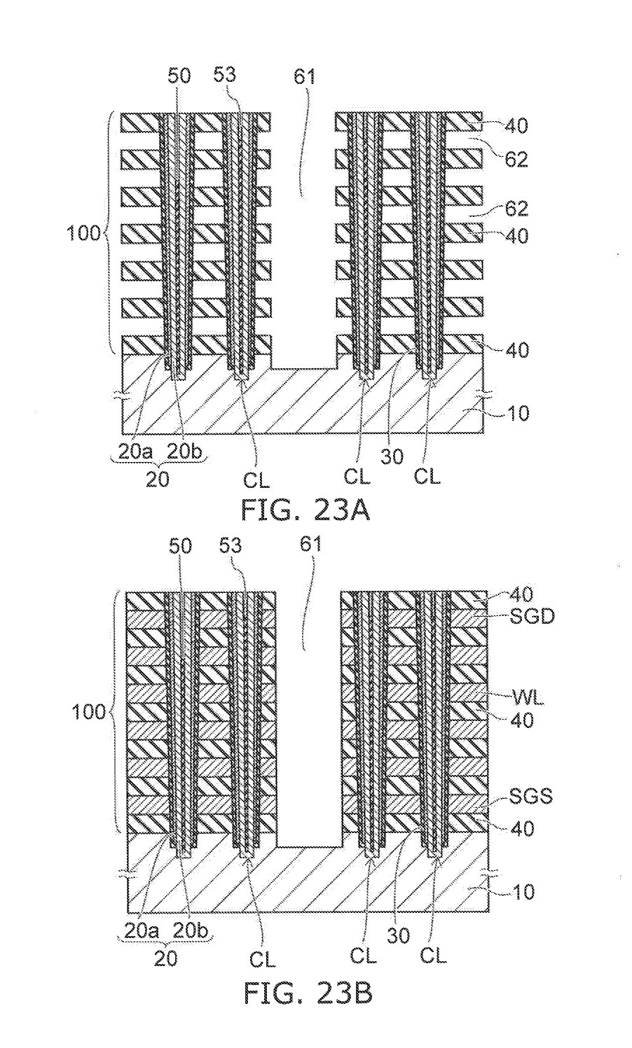

The sacrificial layers 42 are removed by etching through the slit 61. By the removal of the sacrificial layers 42, spaces 62 are formed between the insulating layers 40 as shown in FIG. 23A.

As shown in FIG. 23B, conductive layers are formed in the spaces 62 through the slit 61. The conductive layers constitute the electrode layer WL, the drain side select gate SGD, and the source side select gate SGS.

The drain side select gate SGD is formed in the space 62 of the uppermost layer. The source side select gate SGS is formed in the space 62 of the lowermost layer. The electrode layers WL are formed in the spaces 62 between the uppermost layer and the lowermost layer.

The electrode layers WL, the drain side select gate SGD, and the source side select gate SGS are metal layers, and include e.g. tungsten.

Also in the staircase part, the sacrificial layers 42 are replaced by the electrode layers WL, the drain side select gate SGD, and the source side select gate SGS.

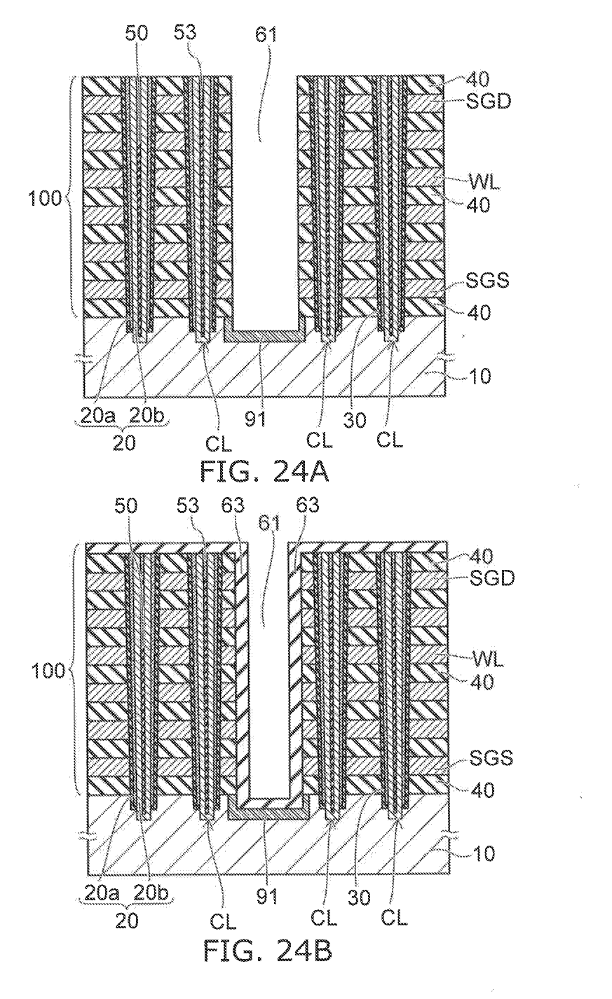

Next, impurity is implanted into the surface of the substrate 10 at the bottom of the slit 61. The implanted impurity is diffused by the subsequent heat treatment. Thus, as shown in FIG. 24A, a contact region 91 is formed in the surface of the substrate 10 at the bottom of the slit 61.

Next, as shown in FIG. 24B, an insulating film 63 is formed on the inner wall (sidewall and bottom part) of the slit 61. The insulating film 63 formed on the bottom part of the slit 61 is removed by RIE technique.

Then, as shown in FIG. 25, a source layer SL is buried in the slit 61. The lower end part of the source layer SL is connected to the substrate 10 through the contact region 91. The lower end of the semiconductor film 20 is electrically connected to the source layer SL through the substrate 10.

Then, the drain side select gate SGD is separated in the Y-direction as shown in FIG. 1. Furthermore, an upper interconnection connected to the bit lines BL and the source layer SL shown in FIG. 1, for example, is formed.

In the multilayer body 100, it is also possible to form an electrode layer WL as a first layer without forming the sacrificial layer 42. In this case, there is no process of replacement from the sacrificial layer 42 to the electrode layer WL.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method for manufacturing a semiconductor device, comprising:
forming first mask films and second mask films on a multilayer body including two or more stacked films, one stacked film including a first layer and a second layer made of a material different from a material of the first layer, the first mask films and the second mask films being arranged alternately in a first direction orthogonal to a stacking direction of the multilayer body, the second mask films being made of materials different from materials of the first mask films;
modifying surfaces of the first mask films and surfaces of the second mask films;
setting back one first mask film in the first direction until a second mask film adjacent to the one first mask film in the first direction is exposed, by etching with selectivity with respect to modified surfaces of the first and second mask films, and broadening an exposed region of the multilayer body; and
etching one stacked film exposed at a surface side in the exposed region of the multilayer body, in the stacking direction.

2. The method according to claim 1, wherein a width in the first direction of one of the first mask films is larger than a width in the first direction of one of the second mask films.

3. The method according to claim 1, wherein the modifying the surfaces of the first and second mask films, the setting back the one first mask film in the first direction, and the etching the one stacked film at the surface side are repeated a plurality of cycles, and a plurality of first layers of the multilayer body are processed into a staircase pattern in the first direction.

4. The method according to claim 1, wherein the modifying the surfaces of the first and second mask films, the setting back the one first mask film in the first direction, and the etching the one stacked film at the surface side are performed in a same chamber.

5. The method according to claim 1, wherein
a film of a material of the first mask film is formed on the multilayer body, and slits are formed in the film, and
the second mask films are buried in the slits.

6. The method according to claim 1, wherein after a second mask film covering a sidewall of the one first mask film on one end side in the first direction is removed by etching using a first gas, the one first mask film is set back in the first direction by etching using a second gas.

7. The method according to claim 1, wherein the first mask films are first silicon films doped with a first impurity, and the second mask films are second silicon films doped with a second impurity different from the first impurity.

8. The method according to claim 7, wherein the first impurity is phosphorus, and the second impurity is boron.

9. The method according to claim 7, wherein the modifying the surfaces of the first and second mask films includes oxidizing surfaces of the first and second silicon films.

10. The method according to claim 9, wherein the surfaces of the first and second silicon films are oxidized by anisotropic plasma processing using oxygen gas.

11. The method according to claim 7, wherein after a second silicon film covering a sidewall of a first silicon film on one end side in the first direction is removed by etching using a fluorine-containing gas, the first silicon film is set back in the first direction by etching using a chlorine-containing gas.

12. The method according to claim 1, wherein the broadening the exposed region of the multilayer body includes:
after setting back the one first mask film in the first direction, setting back the second mask film in the first direction until another first mask film adjacent to the second mask film in the first direction is exposed.

13. The method according to claim 12, wherein the first mask films are silicon films, and the second mask films are metal films.

14. The method according to claim 13, wherein the second mask films are tungsten films.

15. The method according to claim 14, wherein the modifying the surfaces of the first and second mask films includes oxidizing surfaces of the silicon films and surfaces of the tungsten films.

16. The method according to claim 15, wherein the surfaces of the silicon films and the surfaces of the tungsten films are oxidized by anisotropic plasma processing using oxygen gas.

17. The method according to claim 14, wherein one silicon film is set back in the first direction by etching using a chlorine-containing gas, and one tungsten film is set back in the first direction by etching using a gas containing fluorine and oxygen.

18. The method according to claim 12, wherein upper surfaces and sidewalls of the first mask films make an angle smaller than 90°.

19. The method according to claim 3, further comprising:
forming an interlayer insulating film covering the plurality of first layers processed into the staircase pattern;
forming a plurality of holes penetrating through the interlayer insulating film and reaching the first layers; and
forming conductive films in the holes.

20. The method according to claim 1, further comprising:
forming a hole in the multilayer body, the hole extending in the stacking direction;
forming a film including a charge storage film on a sidewall of the hole; and
forming a semiconductor film on a sidewall of the film including the charge storage film.
